(19) United States
(12) Patent Application Publication
(10) Pub. No.: US 2013/0021739 A1
(43) Pub. Date: Jan. 24, 2013

(54) Multi-layer Printed Circuit Board With Power Plane Islands To Isolate Noise Coupling

(71) Applicants: Tae Hong Kim, Round Rock, TX (US); Sang Y. Lee, Austin, TX (US)

(72) Inventors: Tae Hong Kim, Round Rock, TX (US); Sang Y. Lee, Austin, TX (US)

(73) Assignee: INTERNATIONAL BUSINESS MACHINES CORPORATION, Armonk, NY (US)

(21) Appl. No.: 13/187,074

(22) Filed: Jul. 20, 2011

(51) Int. Cl. G06F 1/16; H05K 3/36; H05K 1/11

(52) U.S. Cl. 361/679.31; 174/262; 29/830

(57) ABSTRACT

Multi-layer printed circuit boards (PCB) with power plane islands to isolate noise coupling are provided. In addition, methods and computer program products for manufacturing multi-layer PCBs with power plane islands to isolate noise coupling are provided. Embodiments include a PCB comprising a first power plane coupled to a power supply, the first power plane within a layer of the PCB; a second power plane and a third power plane, the second power plane and the third power plane within another layer of the PCB, the second power plane and the third power plane separated from each other within the other layer of the PCB; and a via bridge structure connecting the first power plane to both the second power plane and the third power plane.

### BACKGROUND OF THE INVENTION

1. Field of the Invention

The field of the invention is data processing, or, more specifically, multi-layer printed circuit boards with power plane islands and methods and computer program products for manufacturing a multi-layer printed circuit board with power plane islands to isolate noise coupling.

2. Description Of Related Art

With increasing speed and decreasing supply voltages in today's high-speed systems, the design of power distribution networks (PDNs) becomes an increasingly difficult challenge for modern technologies. A PDN is designed to provide a stable and uniform voltage for one or more devices and should not cause noise coupling between sensitive high-speed devices. However, for high-speed systems, power plane and ground plane pairs in the PDN form resonators. As a result, when the power/ground plane resonances are excited, the power/ground noise can be significantly large. The noise can produce false switching in digital circuits and malfunctioning in analog circuits.

### SUMMARY OF THE INVENTION

Multi-layer printed circuit boards (PCB) with power plane islands to isolate noise coupling are provided. In addition, methods and computer program products for manufacturing multi-layer PCBs with power plane islands to isolate noise coupling are provided. Embodiments include a PCB comprising a first power plane coupled to a power supply, the first power plane within a layer of the PCB; a second power plane and a third power plane, the second power plane and the third power plane within another layer of the PCB, the second power plane and the third power plane separated from each other within the other layer of the PCB; and a via bridge structure connecting the first power plane to both the second power plane and the third power plane.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth a diagram of an example multi-layer printed circuit board (PCB) with power plane islands to isolate noise coupling according to embodiments of the present invention.

FIG. 2 sets forth a diagram of a multi-layer PCB found in prior art.

FIG. 3 sets forth a diagram of a further example multi-layer PCB with power plane islands to isolate noise coupling according to embodiments of the present invention.

FIG. 4 sets forth a diagram of automated computing machinery comprising an example computer useful in manufacturing a multi-layer PCB with power plane islands to isolate noise coupling according to embodiments of the present invention.

FIG. 5 sets forth a flow chart illustrating an exemplary method for a manufacturing a multi-layer PCB with power plane islands to isolate noise coupling according to embodiments of the present invention.

### DETAILED DESCRIPTION OF EXEMPLARY EMBODIMENTS

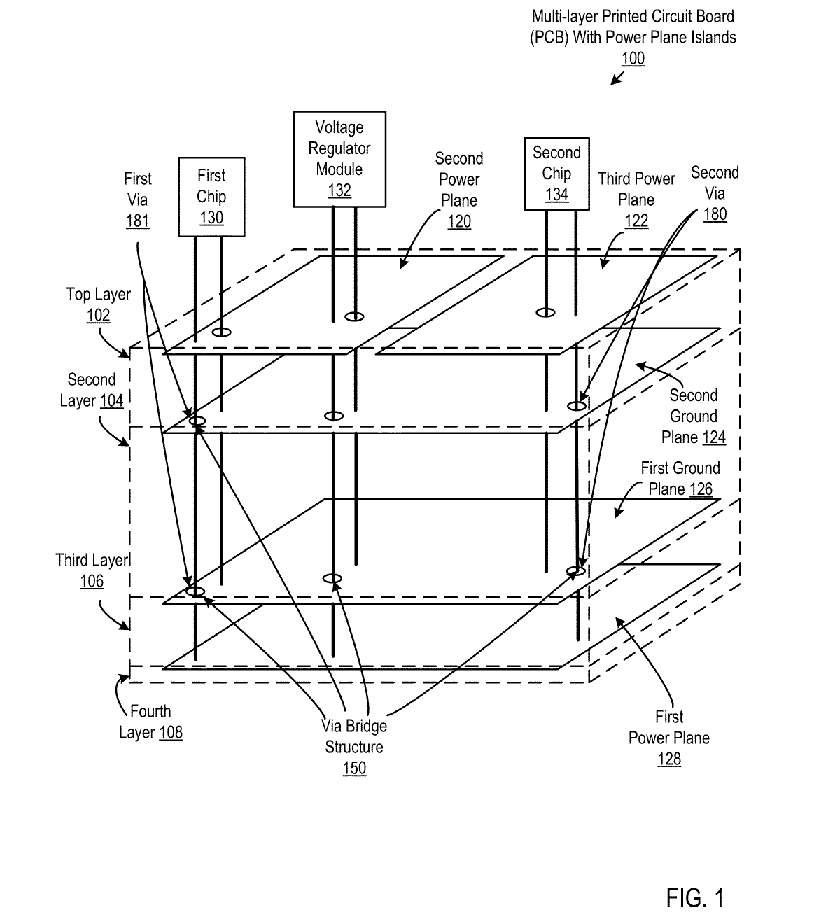

Examples of multi-layer printed circuit boards (PCBs) with power plane islands and methods and computer program products for manufacturing a multi-layer printed circuit board (PCB) with power plane islands to isolate noise coupling in accordance with the present invention are described with reference to the accompanying drawings, beginning with FIG. 1. FIG. 1 sets forth a diagram of an example multi-layer PCB (100) with power plane islands to isolate noise coupling according to embodiments of the present invention.

A PCB is used to mechanically support and electronically connect electrical components using conductive pathways, tracks or signal traces etched from conductive sheets laminated onto a non-conductive substrate. A layer of a PCB provides one or more conductive pathways and insulation from other conductive pathways in other layers of the PCB. A conductive pathway within a layer may be used as a ground plane or a power plane. A ground plane may be configured as a ground potential to help reduce noise and provide a return path for signals transmitted over a power plane. A power plane may be configured to act as a counterpart to a ground plane by providing DC voltage from a power supply to circuits mounted on a PCB. When a power plane within a layer of a PCB is separated and formed into two distinct power planes, the separate power planes may each be called a ‘power plane island.’ Because each of the power plane islands is separated from the other, noise coupling from one integrated circuit chip coupled to one power plane island is blocked from transmitting to another integrated circuit chip coupled to another power plane island.

In the example of FIG. 1, the PCB (100) includes a top layer (102), a second layer (104), a third layer (106), and a fourth layer (108). Although four layers are illustrated, a multi-layer PCB with power plane islands to isolate noise coupling according to embodiments of the present invention may include any number of layers greater than two. The PCB (100) includes a first power plane (128) in the fourth layer (108), a second power plane (120) in the top layer (102), and a third power plane (122) in the top layer (102). Although the second power plane (120) and the third power plane (122) are within the same layer of the PCB, each power plane is separated from each other within the layer and thus is referred to as a ‘power plane island.’ The PCB (100) of FIG. 1 also includes a first ground plane (126) within the third layer (106) and a second ground plane (124) within the second layer (104). In the example of FIG. 1, the first ground plane (126) is configured to act as a ground counterpart to signals transmitted over the first power plane (128) and the second ground plane (124) is configured to act as a ground counterpart to signals transmitted over either the second power plane (120) or the third power plane (122).

The PCB (100) of FIG. 1 includes a via bridge structure (150). A via bridge structure is a plurality of vertical electrical connections between different layers of conductors in a printed circuit board. Typically, a via is a hole that connects a conductive pathway on one layer of a PCB with another conductive pathway on another layer of a PCB through one or more other conductive pathways. Vias may be formed by drilling holes in a conductive pathway and electroplating the hole, or any other method that will occur to readers of skill in the art. In the example of FIG. 1, a first via (181) is formed through the second layer (104) and the third layer (106) of the PCB (100) so that a conductive pathway is formed between the second power plane (120) and the first power plane (128). A second via (180) is formed through the second layer (104) and the third layer (106) of the PCB (100) so that a conductive pathway is formed between the third power plane(122) and the first power plane (128). That is, the first via (181) and the second via (180) form holes through the second ground plane (124) and the first ground plane (126). The PCB (100) of FIG. 1 also includes vias that couple the ground planes together. That is, holes are formed through the power planes such that the ground planes have a shared conductive pathway.

The PCB (100) of FIG. 1 also includes a voltage regulator module (132) that is coupled to each of the power planes and the ground planes. A voltage regulator module is an electrical regulator that is designed to automatically maintain a constant voltage level. The voltage regulator module (132) is configured to provide a single DC voltage to each of the power planes.

In the example of FIG. 1, a first integrated circuit chip (130) is directly coupled to the second power plane (120) and a second integrated circuit chip (134) is directly coupled to the third power plane (122). An integrated circuit chip is an electrical circuit that typically includes semiconductor devices, as well as passive components, that are bonded to a substrate or circuit board. Because the second power plane (120) and the third power plane (122) are both power plane islands, noise coupling from the first chip (130) is blocked from transmitting to the second chip (134) between the second power plane (120) and the third power plane (122). Reducing noise, reduces the chance that the noise will propagate off the PCB and turn into radiated electromagnetic interference (EMI).

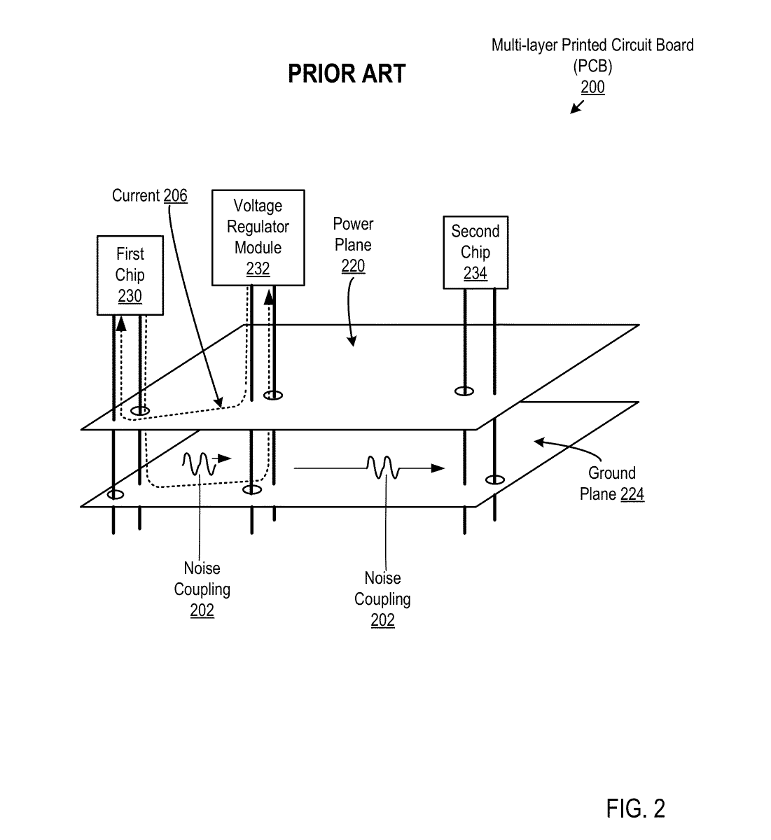

To illustrate the problem associated with noise coupling transmission between chips sharing a power plane, FIG. 2 sets forth a diagram of a multi-layer PCB (200) found in prior art. The PCB (200) of FIG. 2 includes a first integrated circuit chip (230) and a second integrated circuit chip (234) coupled to a power plane (220) and a ground plane (224).

In the example of FIG. 2, a voltage regulator module (232) provides the power plane (220) with DC voltage for powering the first chip (230) and the second chip (234). Current (206) flows from the voltage regulator module (232) to the first chip (230) on the power plane (220) and back from the first chip (230) to the voltage regulator module (232) on the ground plane (224). The current (206) tends to follow the least inductive path. Because of that, the current (206) will follow the closest power plane. In the example of FIG. 2, the noise coupling (202) generated by the return signal on the ground plane (224) will continue to propagate on the ground plane (224), thus impacting the return signals generated by the second chip (234).

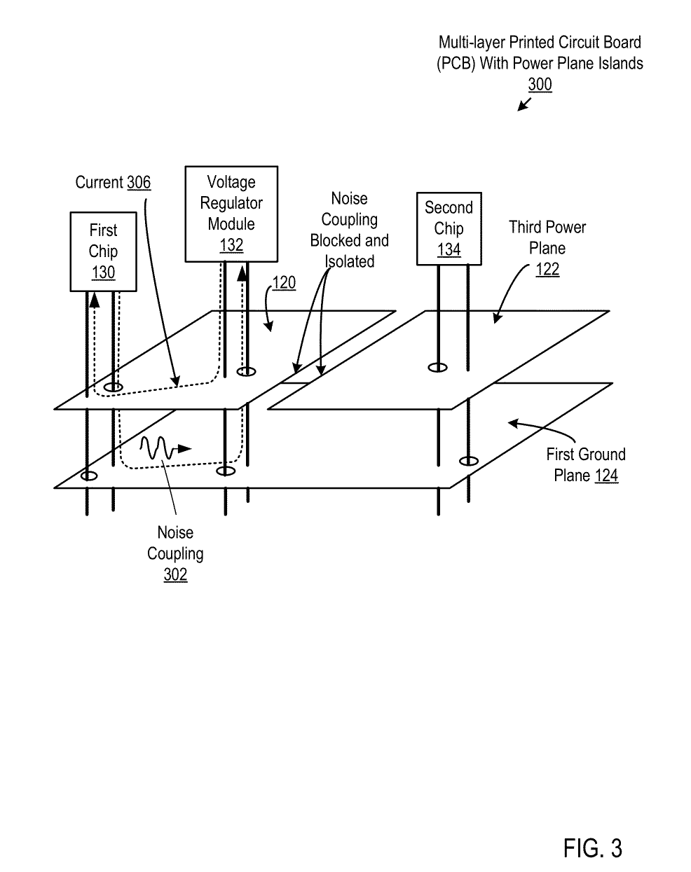

FIG. 3 illustrates isolation of noise coupling in an example multi-layer PCB (300) with power plane islands according to embodiments of the present invention. The PCB (300) of FIG. 3 is similar to the PCB (100) of FIG. 1 in that it includes the first chip (130) coupled to the second power plane (120) and the first ground plane (124); the second chip (134) coupled to the third power plane (122) and the first ground plane (124).

In the example of FIG. 3, a voltage regulator module (132) provides the third power plane (122) and the second power plane (120) with DC voltage for powering the first chip (130) and the second chip (134). Current (306) flows from the voltage regulator module (132) to the first chip (130) on the third power plane (120) and back from the first chip (130) to the voltage regulator module (132) on the ground plane (124). The current (306) tends to follow the least inductive path and therefore will follow the closest power plane. In the example of FIG. 3, the third power plane (122) is separated from the second power plane (120). Therefore, the noise coupling (302) generated by the return signal on the ground plane (124) will follow the closest plane which is the third power plane (120). In this example, noise coupling (302) is blocked from traveling along the first ground plane (124) and thus from interfering with the second chip (134). By placing power plane islands on the top layer as opposed to other layers of the PCB, the advantages of the present invention, such as reduced electromagnetic radiation may be more pronounced as the distance of the conductive pathway between the first chip (130) and the voltage regulator module (132) is reduced. Accordingly, reducing the length of the conductive pathway reduces the electromagnetic radiation levels generated by signals traveling along the conductive pathway.

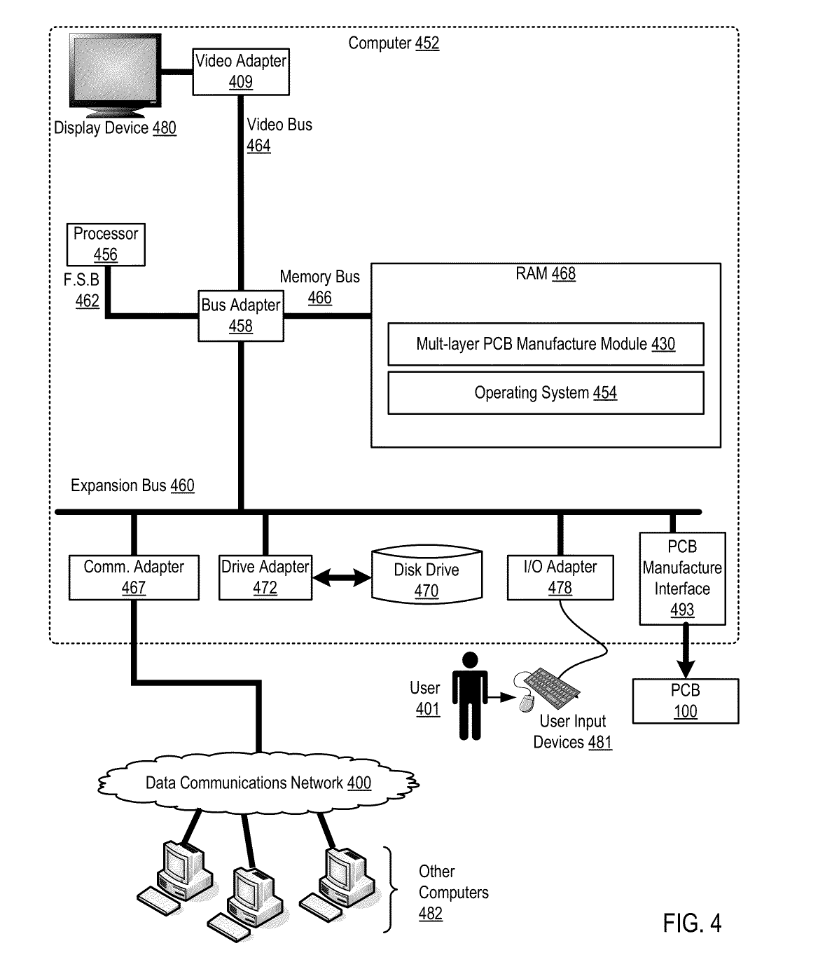

To manufacture a multi-layer printed circuit board (PCB) with power plane islands, a computer that includes computer program instructions for manufacturing PCB is used. For further explanation, therefore, FIG. 4 sets forth a block diagram of automated computing machinery comprising an exemplary computer (452) useful in manufacturing a multi-layer printed circuit board (PCB) with power plane islands to isolate noise coupling according to embodiments of the present invention. The computer (452) of FIG. 4 includes at least one computer processor (456) or ‘CPU’ as well as random access memory (468) (‘RAM’) which is connected through a high speed memory bus (466) and bus adapter (458) to processor (456) and to other components of the computer (452).

Stored in RAM (468) is a multi-layer PCB manufacture module (430) that includes computer program instructions for manufacturing a multi-layer PCB with power plane islands to isolate noise coupling according to embodiments of the present invention. As part of the manufacturing of a PCB, the manufacture module (430) may act as a design computer that controls the design of a PCB. That is, the manufacture module (430) may manufacture a PCB with power plane islands by controlling PCB design information. PCB design information may include physical positioning information of a packaged semiconductor device of a PCB. The manufacture module (430) may be configured to transform the PCB design information to generate a data file, such as a GERBER file with data that includes new physical positioning information of the PCB, as well as layout of electrical connections such as traces and vias. That is, the manufacture module (430) may be configured to generate a PCB design to create the multi-layer PCB (100) of FIG. 1. In other embodiments, the data file generated by the transformed PCB design information may have a format other than a GERBER format.

In addition, the manufacture module (430) may also be configured to assemble a PCB as part of the manufacture process. That is, the manufacture module (430) may use a GERBER file to create PCBs manufactured in accordance with the design information stored in the GERBER file. For example, the manufacture module (430) may use the GERBER file to perform various steps of a PCB production process to create the PCB (100) of FIG. 1. That is, the manufacture module (430) may include program instructions that cause the exemplary computer (352) to populate a PCB with electrical components and generate signal traces and conductive pathways on the PCB (100). For example, the manufacture module (430) may use a PCB manufacture interface (493) to manufacture the PCB (100) according to embodiments of the present invention.

Specifically, the multi-layer PCB manufacture module (430) includes computer program instructions that when executed by the processor (456) cause the processor (456) to provide a first power plane within a layer of the PCB; provide a second power plane and a third power plane within another layer of the PCB, the second power plane and the third power plane separated from each other within the other layer of the PCB; and provide a via bridge structure connecting the first power plane to both the second power plane and the third power plane.

Also stored in RAM (468) is an operating system (454). Operating systems useful in manufacturing a multi-layer printed circuit board (PCB) with power plane islands to isolate noise coupling according to embodiments of the present invention include UNIX™, Linux™, Microsoft XP™, AIX™, IBM's i5/OS™ and others as will occur to those of skill in the art. The operating system (454) and the multi-layer PCB manufacture module (430) in the example of FIG. 4 are shown in RAM (468), but many components of such software typically are stored in non-volatile memory also, such as, for example, on a disk drive (470).

The computer (452) of FIG. 4 includes disk drive adapter (472) coupled through expansion bus (460) and bus adapter (458) to processor (456) and other components of the computer (452). Disk drive adapter (472) connects non-volatile data storage to the computer (452) in the form of disk drive (470). Disk drive adapters useful in computers for a multi-layer printed circuit board (PCB) with power plane islands to isolate noise coupling according to embodiments of the present invention include Integrated Drive Electronics (‘IDE’) adapters, Small Computer System Interface (‘SCSI’) adapters, and others as will occur to those of skill in the art. Non-volatile computer memory also may be implemented for as an optical disk drive, electrically erasable programmable read-only memory (so-called ‘EEPROM’ or ‘Flash’ memory), RAM drives, and so on, as will occur to those of skill in the art.

The example computer (452) of FIG. 4 includes one or more input/output (‘I/O’) adapters (478). I/O adapters implement user-oriented input/output through, for example, software drivers and computer hardware for controlling output to display devices such as computer display screens, as well as user input from user input devices (481) such as keyboards and mice. The example computer (452) of FIG. 4 includes a video adapter (409), which is an example of an I/O adapter specially designed for graphic output to a display device (480) such as a display screen or computer monitor. Video adapter (409) is connected to processor (456) through a high speed video bus (464), bus adapter (458), and the front side bus (462), which is also a high speed bus.

The exemplary computer (452) of FIG. 4 includes a communications adapter (467) for data communications with other computers (482) and for data communications with a data communications network (400). Such data communications may be carried out serially through RS-232 connections, through external buses such as a Universal Serial Bus (‘USB’), through data communications networks such as IP data communications networks, and in other ways as will occur to those of skill in the art. Communications adapters implement the hardware level of data communications through which one computer sends data communications to another computer, directly or through a data communications network. Examples of communications adapters useful for a multi-layer printed circuit board (PCB) with power plane islands to isolate noise coupling according to embodiments of the present invention include modems for wired dial-up communications, Ethernet (IEEE 802.3) adapters for wired data communications network communications, and 802.11 adapters for wireless data communications network communications.

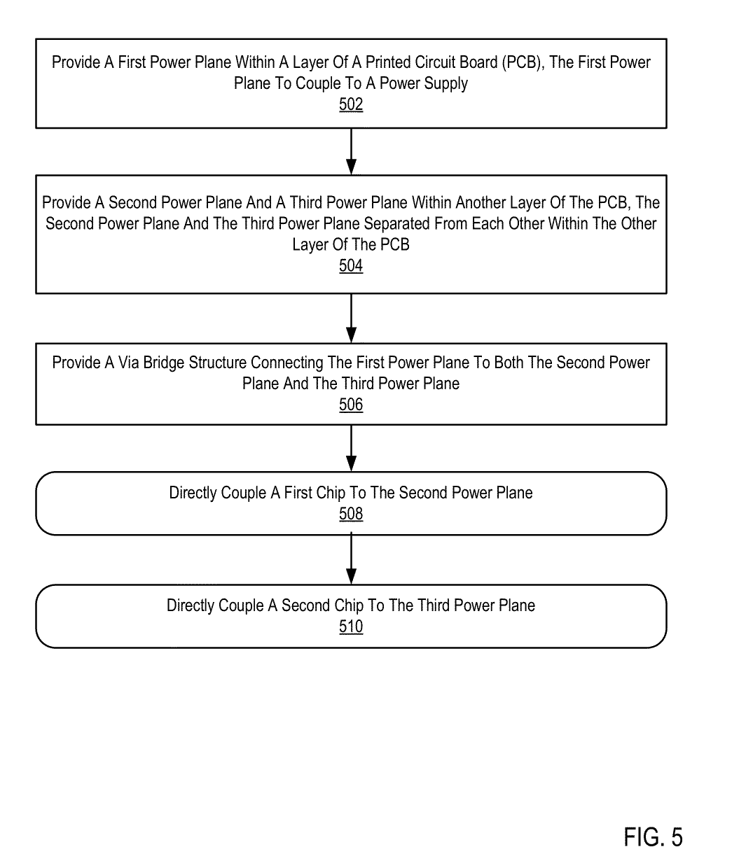

For further explanation, FIG. 5 sets forth a flow chart illustrating an exemplary method for manufacturing a multi-layer printed circuit board (PCB) with power plane islands to isolate noise coupling according to embodiments of the present invention. The method of FIG. 5 includes providing (502) a first power plane within a layer of the PCB, the first power plane to couple to a power supply. Providing (502) a first power plane within a layer of the PCB may be carried out by generating PCB design information that specifies a first power plane island within a layer of the PCB; and generating a PCB according to the PCB design information that specifies a first power plane island within a layer of the PCB.

The method of FIG. 5 also includes providing (504) a second power plane and a third power plane within another layer of the PCB, the second power plane and the third power plane separated from each other within the other layer of the PCB. Providing (504) a second power plane and a third power plane within another layer of the PCB may be carried out by generating PCB design information that specifies a second power plane island and a third power plane island within another layer of the PCB; and generating a PCB according to the PCB design information that specifies a second power plane island and a third power plane island within another layer of the PCB.

The method of FIG. 5 includes providing (506) a via bridge structure connecting the first power plane to both the second power plane and the third power plane. Providing (506) a via bridge structure connecting the first power plane to both the second power plane and the third power plane may be carried out by generating PCB design information that specifies a series of vias, through-holes, conductive pathways, and insulation to connect the first power plane to both the second power plane and the third power plane; and generating a PCB according to the PCB design information that specifies a series of vias, through-holes, conductive pathways, and insulation to connect the first power plane to both the second power plane and the third power plane.

The method of FIG. 5 may optionally include directly coupling (508) a first chip to the second power plane. Directly coupling (508) a first chip to the second power plane may be carried out by generating PCB design information that specifies conductive pathway connections between the first chip and the traces on the PCB; and generating a PCB according to the PCB design information that specifies conductive pathway connections between the first chip and the traces on the PCB, including populating a PCB with integrated circuit chips.

The method of FIG. 5 may optionally also include directly coupling (510) a second chip to the third power plane. Directly coupling (510) a second chip to the third power plane may be carried out by generating PCB design information that specifies conductive pathway connections between the second chip and the traces on the PCB; and generating a PCB according to the PCB design information that specifies conductive pathway connections between the second chip and the traces on the PCB, including populating a PCB with integrated circuit chips.

Exemplary embodiments of the present invention are described largely in the context of a fully functional computer system for a multi-layer printed circuit board (PCB) with power plane islands to isolate noise coupling. Readers of skill in the art will recognize, however, that the present invention also may be embodied in a computer program product disposed upon computer readable storage media for use with any suitable data processing system. Such computer readable storage media may be any storage medium for machine-readable information, including magnetic media, optical media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps of the method of the invention as embodied in a computer program product. Persons skilled in the art will recognize also that, although some of the exemplary embodiments described in this specification are oriented to software installed and executing on computer hardware, nevertheless, alternative embodiments implemented as firmware or as hardware are well within the scope of the present invention.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described above with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A multi-layer printed circuit board (PCB) with power plane islands to isolate noise coupling, the PCB comprising:
a first power plane coupled to a power supply, the first power plane within a layer of the PCB;
a second power plane and a third power plane, the second power plane and the third power plane within another layer of the PCB, the second power plane and the third power plane separated from each other within the other layer of the PCB; and
a via bridge structure connecting the first power plane to both the second power plane and the third power plane.

2. The PCB of claim 1 wherein the second power plane and the third power plane are within the top layer of the PCB.

3. The PCB of claim 1 wherein the via bridge structure connects through multiple layers of the PCB the first power plane to the second power plane and the third power plane, at least one the multiple layers includes a ground plane.

4. The PCB of claim 1 wherein the via bridge structure includes:
a first via connecting the first power plane to the second power plane; and
a second via connecting the first power plane to the third power plane.

5. The PCB of claim 1 further comprising:
a first chip directly coupled to the second power plane; and
a second chip directly coupled to the third power plane.

6. An apparatus that includes a multi-layer printed circuit board (PCB) with power plane islands to isolate noise coupling, the apparatus comprising:
a computer processor;
a computer memory operatively coupled to the computer processor;
a first power plane coupled to a power supply, the first power plane within a layer of the PCB;
a second power plane and a third power plane, the second power plane and the third power plane within another layer of the PCB, the second power plane and the third power plane separated from each other within the other layer of the PCB; and
a via bridge structure connecting the first power plane to both the second power plane and the third power plane.

7. The apparatus of claim 6 wherein the second power plane and the third power plane are within the top layer of the PCB.

8. The apparatus of claim 6 wherein the via bridge structure connects through multiple layers of the PCB the first power plane to the second power plane and the third power plane, at least one the multiple layers includes a ground plane.

9. The apparatus of claim 6 wherein the via bridge structure includes:
a first via connecting the first power plane to the second power plane; and
a second via connecting the first power plane to the third power plane.

10. The apparatus of claim 6 further comprising:
a first chip directly coupled to the second power plane; and
a second chip directly coupled to the third power plane.

11. A method of manufacturing a multi-layer printed circuit board (PCB) with power plane islands to isolate noise coupling, the method comprising:
providing a first power plane within a layer of the PCB, the first power plane to couple to a power supply;
providing a second power plane and a third power plane within another layer of the PCB, the second power plane and the third power plane separated from each other within the other layer of the PCB; and
providing a via bridge structure connecting the first power plane to both the second power plane and the third power plane.

12. The method of claim 11 wherein the second power plane and the third power plane are within the top layer of the PCB.

13. The method of claim 11 wherein the via bridge structure connects through multiple layers of the PCB the first power plane to the second power plane and the third power plane, at least one the multiple layers includes a ground plane.

14. The method of claim 11 wherein the via bridge structure includes:
a first via connecting the first power plane to the second power plane; and
a second via connecting the first power plane to the third power plane.

15. The method of claim 11 further comprising:
directly coupling a first chip to the second power plane; and
directly coupling a second chip to the third power plane.

16. A computer program product for manufacturing a multi-layer printed circuit board (PCB) with power plane islands to isolate noise coupling, the computer program product disposed upon a computer readable storage medium, the computer program product comprising computer program instructions capable, when executed, of causing a computer to carry out the steps of:
providing a first power plane within a layer of the PCB, the first power plane to couple to a power supply;
providing a second power plane and a third power plane within another layer of the PCB, the second power plane and the third power plane separated from each other within the other layer of the PCB; and
providing a via bridge structure connecting the first power plane to both the second power plane and the third power plane.

17. The computer program product of claim 16 wherein the second power plane and the third power plane are within the top layer of the PCB.

18. The computer program product of claim 16 wherein the via bridge structure connects through multiple layers of the PCB the first power plane to the second power plane and the third power plane, at least one the multiple layers includes a ground plane.

19. The computer program product of claim 16 wherein the via bridge structure includes:
a first via connecting the first power plane to the second power plane; and
a second via connecting the first power plane to the third power plane.

20. The computer program product of claim 16 further comprising computer program instructions capable, when executed, of causing a computer to carry out the steps of:
directly coupling a first chip to the second power plane; and
directly coupling a second chip to the third power plane.
